(19) United States
(12) Patent Application Publication
(10) Pub. No.: US 2009/0166847 A1
(43) Pub. Date: Jul. 2, 2009

(54) SEMICONDUCTOR CHIP PACKAGE

(75) Inventor: Shu-Liang Nin, Taoyuan County (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 12/060,701

(22) Filed: Apr. 1, 2008

(30) Foreign Application Priority Data
Dec. 31, 2007 (TW) TW96151440

(51) Int. Cl. H01L 23/04

(52) U.S. Cl. 257/698; 257/E23.181

(57) ABSTRACT

A semiconductor chip package is provided. The semiconductor chip package comprises a package substrate having a first surface and a second surface opposite to the first surface. A through hole extends through the package substrate. A semiconductor chip is disposed on the first surface of the package substrate, wherein a bottom surface of the semiconductor chip covers one end of the through hole. At least two bonding fingers are disposed on the second surface of the package substrate and arranged on sides of the through hole. A conductive line is disposed on the second surface of the package substrate and between the two bonding fingers and the through hole, wherein two terminals of the conductive line are electrically connected to the two bonding fingers, respectively.

### BACKGROUND OF THE INVENTION

1. Field of the Invention

The invention relates to a semiconductor chip package and, more particularly, to a semiconductor chip package with low impedance.

2. Description of the Related Art

Semiconductor chip packages have various standard specifications for size, shape, number of leads/ball pads, spacing or length for convenient manufacturing processes and/or printed circuit boards (PCBs) adaptability. Also, all production lines or equipments related to semiconductor chip packages have commonality for standardization. However, semiconductor chip packages may not achieve excellent electrical performances due to limitations of those standard specifications, especially impedance of power net including ground lines (GND) or electrical power lines (VDD). In conventional technologies, impedance of power net may be reduced by using multi-layer printed circuit boards (PCBs) for better arrangement or using additional decoupling capacitors. The aforementioned impedance reducing technologies, however, may increase manufacturing cost.

Thus, a novel and reliable semiconductor chip package with lower impedance and manufacturing cost is needed.

### BRIEF SUMMARY OF INVENTION

To solve the above-described problems, a novel semiconductor chip package is provided. According to one feature of the present invention, the semiconductor chip package comprises a package substrate having a first surface and a second surface opposite to the first surface. A through hole is defined to extend the package substrate. A semiconductor chip is disposed on the first surface of the package substrate to cover one end of the through hole. Bonding fingers are disposed on the second surface of the package substrate and arranged on sides of the through hole. At least one conductive line is disposed on the second surface of the package substrate and located between the bonding fingers and the through hole, wherein the at least one conductive line has at least two terminals electrically connected to at least two of the bonding fingers, respectively.

According to one feature of the present invention, the semiconductor chip package comprises a package substrate, a plurality of ball pads formed on the package substrate and divided into sets electrical characteristics, a plurality of bonding fingers formed on the package substrate and a plurality of conductive traces electrically connecting the plurality of ball pads and the plurality of bonding fingers, wherein at least one conductive line is electrically connected to two of the plurality of bonding fingers which are electrically connected to at least one set of the ball pads of an electrical characteristic for decreasing impedance of the semiconductor chip package.

According to one feature of the present invention, wherein one set of the ball pads having same electric characteristic is adapted to connect to ground.

According to one feature of the present invention, wherein one set of the ball pads having same electric characteristic is adapted to connect to power.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1a shows a cross section of an exemplary embodiment of a semiconductor chip package of the invention.

FIG. 1b shows a schematic bottom view of an exemplary embodiment of a semiconductor chip package of the invention.

FIG. 2 shows an impedance comparison between an exemplary embodiment of a semiconductor chip package of the invention and the conventional semiconductor chip package.

### DETAILED DESCRIPTION OF INVENTION

The following description is of a mode of carrying out the invention. This description is made for the purpose of explaining the general principles of the invention and should not be taken in a limiting sense. The scope of the invention is best determined by reference to the appended claims.

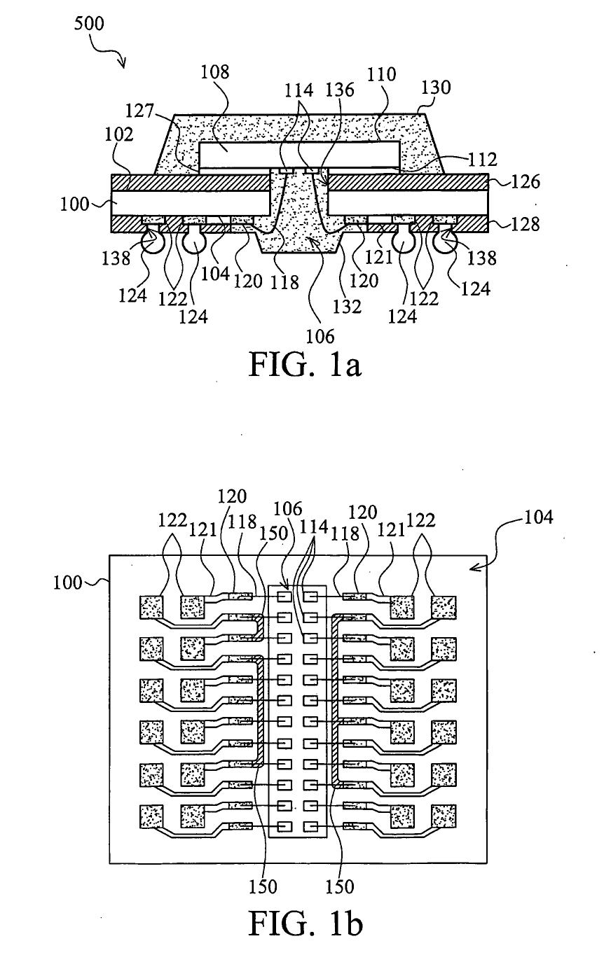

FIG. 1a shows a cross section of an exemplary embodiment of a semiconductor chip package of the invention. FIG. 1b shows a schematic bottom view of an exemplary embodiment of a semiconductor chip package of the invention. Wherever possible, the same reference numbers are used in the drawings and the descriptions to refer to the same or like parts.

FIG. 1a shows a cross section of an exemplary embodiment of a semiconductor chip package 500 of the invention. FIG. 1b is a schematic bottom view of an exemplary embodiment of a semiconductor chip package of the invention showing a design of a package substrate 100. In FIG. 1b, a second packing material 132, a second solder mask layer 128 and solder balls 124 as the uppermost level of the package substrate 100 as shown on FIG. 1a are not illustrated for expediency of description, but not limited to the disclosure herein. In an exemplary embodiment of the invention, the semiconductor chip package 500 may comprise window ball grid array (WBGA) package. As shown in FIG. 1a, the semiconductor chip package 500 may comprise a package substrate 100 having a first surface 102 and a second surface 104 opposite to the first surface 102. In one embodiment, the package substrate 100 may comprise plastic materials, ceramic materials or the like. A through hole 106 extends through the package substrate 100. A semiconductor chip 108 having a top surface 110 and a bottom surface 112 is mounted on the first surface 102 of the package substrate 100 by an adhesive material 127 such as epoxy, wherein the bottom surface 112 of the semiconductor chip 108 covers one end of the through hole 106. Additionally, the semiconductor chip 108 may comprises a plurality of bonding pads 114 disposed on the bottom surface 112 of the semiconductor chip 108 and facing to the through hole 106. The bonding pads 114 may be used to provide a plurality of sets with electrical characteristics, for example, to provide an electrical connection for input/output (I/O), electrical power supply or grounding connections of the semiconductor chip 108. In one embodiment, the bonding pads 114 may comprise conductive materials, such as, Cu, Sn, Ni, Cr, and Ti or combinations thereof. As shown in FIGS. 1a and 1b, the semiconductor chip package 500 may comprise a plurality of bonding fingers 120 disposed on the second surface 104 of the package substrate 100 and arranged on sides of the through hole 106. Each of the bonding fingers 120 may be electrically connected to one of the bonding pads 114 by one of bonding wires 118 through the through hole 106 respectively. A plurality of conductive lines 150 is disposed on the second surface 104 of the package substrate 100 and located between the bonding fingers 120 and the through hole 106, wherein at least two terminals of each of the conductive lines 150 are electrically connected to any two of the bonding fingers 120, respectively. As shown in FIGS. 1a and 1b, the semiconductor chip package 500 may further comprise a plurality of ball pads 122 disposed on the second surface 104 of the package substrate 100. A plurality of conductive traces 121 is disposed on the second surface 104 of the package substrate 100, wherein each of the conductive traces 121 is electrically connected to one of the bonding fingers 120 and one of the ball pads 122 respectively. In one embodiment, the bonding fingers 120, the conductive traces 121 and the ball pads 122 may comprise the same materials, for example, Au, Ag, Cu, W, Ni, Si, Al, Mo or alloys thereof. A plurality of solder balls 124 may be disposed on the second surface 104 of the package substrate 100. Each of the solder balls 124 may be disposed on the ball pads 122 by soldering, electrically connected to one of the ball pads 122. The solder balls 124 may be electrically to an underlying printed circuit board (PCB) (not shown) to provide electrical connections, for example, input/output (I/O) connections, of the semiconductor chip 108.

As shown in FIGS. 1a and 1b, the semiconductor chip package 500 may further comprise a first packaging material 130 encapsulating the semiconductor chip 108 and a portion of the first surface 102 of the package substrate 100. A second packaging material 132 fills the through hole 106, encapsulating the bonding wires 118, the conductive lines 150 and the bonding fingers 120. In one embodiment, the first packaging material 130 and the second packaging material 132 may comprise polymer materials, for example, epoxy resin. The semiconductor chip package 500 may further comprise a first solder mask layer 126 disposed on the first surface 102 of the package substrate 100, between the package substrate 100 and the semiconductor chip 108, wherein the first solder mask layer 126 has a first opening 136 to expose the through hole 106. A second solder mask layer 128 is disposed on the second surface 104 of the package substrate 100, covering the conductive traces 121 and a portion of the ball pads 122, wherein the second solder mask layer 128 has a plurality of second openings 138 to expose the ball pads 122. In one embodiment, the first solder mask layer 126 may be used to prevent the package substrate 100 from rapid oxidation in air. The second solder mask layer 128 may be used to prevent short from unnecessary solder between the adjacent ball pads 122 during mounting of the solder balls 124 on the ball pads 122. Also, The second solder mask layer 128 may be used to prevent conductive traces 121 from rapid oxidation in air. In addition, the second solder mask layer 128 may leave openings; for example, second openings 138, on the ball pads 122 positions without covering the ball pads 122.

As shown in FIG. 1b, the conductive lines 150 are electrically connected to at least two the bonding fingers 120. The conductive lines 150 may be disposed in a region between the through hole 106 and the bonding fingers 120, adjacent to an edge of the through hole 106. The conductive lines 150 may be substantially parallel to an edge of the through hole 106, and the bonding fingers 120 which are electrically connected to the conductive lines 150 may be electrically connected to ground lines (GND) or electrical power lines (VDD).

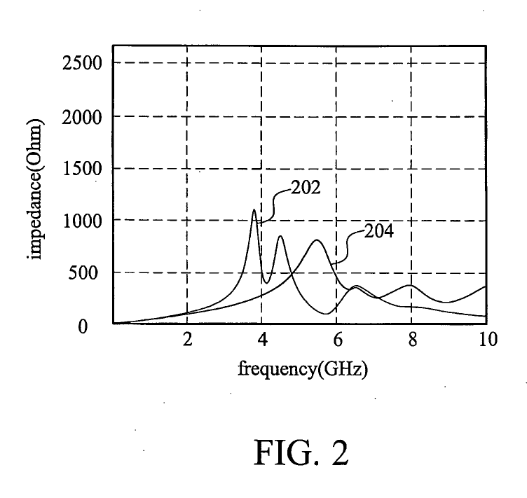

FIG. 2 shows impedance to frequency comparison between an exemplary embodiment of a semiconductor chip package of the invention and the conventional semiconductor chip package, showing as curves 202 and 204. As shown in FIG. 2, an impedance curve 204 at different frequency is lower than an impedance curve 202. As described above, when compared with the conventional semiconductor chip package, an exemplary embodiment of a semiconductor chip package of the invention, which has conductive lines 150 connected to at least two ground lines or electrical power lines with a location between the through hole 106 and the bonding fingers 120, has lower impedance at different frequencies. The conductive lines 150 may provide a ground or electrical power path with lower impedance even if each of the bonding pads 114 or the ball pads 120 of the semiconductor chip 108 has a fixed corresponding input/output position for standard specifications. Therefore, electrically performances of the semiconductor chip package 500 may be improved.

An exemplary embodiment of a semiconductor chip package 500 uses a conductive line 150 electrically connected at least two bonding fingers 120, which are electrically connected to ground lines (GND) or electrical power lines (VDD), respectively. The conductive lines 150 are disposed on the package substrate 100, in a region between the through hole 106 and the bonding fingers 120, to reduce impedance of ground or electrical power path and does not require multi-layer print circuit boards (PCB) or decoupling capacitors for additional costs. Therefore, efficiently improving electrical performance of the semiconductor chip package 500.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor chip package, comprising:
a package substrate having a first surface and a second surface opposite to the first surface;
a through hole extending through the package substrate;
a semiconductor chip disposed on the first surface of the package substrate to cover one end of the through hole;
bonding fingers disposed on the second surface of the package substrate and arranged on sides of the through hole; and
at least one conductive line disposed on the second surface of the package substrate to be located between the bonding fingers and the through hole, wherein the at least one conductive line has at least two terminals electrically connected to two of the bonding fingers.

2. The semiconductor chip package as claimed in claim 1, wherein one of the bonding fingers is adapted to electrically connect to ground.

3. The semiconductor chip package as claimed in claim 1, wherein one of the bonding fingers is adapted to electrically connect to power.

4. The semiconductor chip package as claimed in claim 1, wherein the at least one conductive line is adjacent to an edge of the through hole.

5. The semiconductor chip package as claimed in claim 1, wherein the at least one conductive line is substantially parallel to an edge of the through hole.

6. The semiconductor chip package as claimed in claim 1 further comprising:
a plurality of bonding pads disposed on the bottom surface of the semiconductor chip and facing to through hole; and
a plurality of bonding wires extending through the through hole, wherein each of the plurality of bonding wires is electrically connected to one of the bonding pads and one of the bonding fingers.

7. The semiconductor chip package as claimed in claim 5 further comprising:
a plurality of ball pads disposed on the second surface of the package substrate;
a plurality of conductive traces disposed on the second surface of the package substrate, wherein each of the plurality of conductive traces is electrically connected to one of the bonding fingers and one of the plurality of ball pads; and
a plurality of solder balls disposed on the second surface of the package substrate, wherein each of the solder balls is electrically connected to one of the ball pads.

8. The semiconductor chip package as claimed in claim 5, further comprising:
a first packaging material encapsulating the semiconductor chip and a portion of the first surface of the package substrate;
a second packaging material filling the through hole to encapsulate the plurality of bonding wires_and the bonding fingers.

9. The semiconductor chip package as claimed in claim 7 further comprising:
a first solder mask layer disposed on the first surface of the package substrate to be located between the package substrate and the semiconductor chip, wherein the first solder mask layer has a first opening to expose the through hole; and
a second solder mask layer disposed on the second surface of the package substrate to cover a portion of the ball pads, wherein the second solder mask layer has a plurality of second openings to expose the ball pads.

10. The semiconductor chip package as claimed in claim 9, wherein the bonding fingers, the plurality of conductive traces and the plurality of ball pads are formed of a material selected from the group consisting of Au, Ag, Cu, W, Ni, Si, Al, Mo and alloys thereof.

11. A semiconductor chip package, comprising:
a package substrate;
a plurality of ball pads formed on the package substrate and divided into sets with electrical characteristics;
a plurality of bonding fingers formed on the package substrate;
a plurality of conductive traces electrically connecting the plurality of ball pads and the plurality of bonding fingers, wherein improvements comprise:
at least one conductive line electrically connecting two of the plurality of bonding fingers which are electrically connected to at least one set of the ball pads of an electrical characteristic for decreasing impedance of the semiconductor chip package.

12. The semiconductor chip package as claimed in claim 11, wherein one set of the ball pads having same electrical characteristic is adapted to connect to ground.

13. The semiconductor chip package as claimed in claim 11, wherein one set of the ball pads having same electrical characteristic is adapted to connect to power.
